(19) United States
(12) Patent Application Publication
(10) Pub. No.: US 2013/0235523 A1
(43) Pub. Date: Sep. 12, 2013

(54) SERVER

(71) Applicants: KANG WU, Shenzhen City (CN); WEI-DONG CONG, Shenzhen City (CN)

(72) Inventors: KANG WU, Shenzhen City (CN); WEI-DONG CONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/568,052

(22) Filed: Aug. 6, 2012

(30) Foreign Application Priority Data
Mar. 12, 2012 (CN) 201210063114.1

(51) Int. Cl. H05K 7/20

(52) U.S. Cl. 361/695

(57) ABSTRACT

A server includes a backplane, first and second groups of motherboards, and first and second groups of fans. When the first group of motherboards are not operating, no power is output by the group. The first group of fans is not powered on. When the second group of motherboard are not operating, no power is output by the group. The second group of fans is not powered on. When at least one motherboard in the first group of motherboards is operating, the working motherboard outputs power to the first group of fans. The first group of fans are powered on. When at least one motherboard in the second group of motherboards is operating, the working motherboard outputs power to the second group of fans. The second group of fans is powered on.

### BACKGROUND

1. Technical Field

The present disclosure relates to a server.

2. Description of Related Art

In a cabinet, a plurality of fans is used for cooling servers. A power supply unit supplies power for the fans in the cabinet. If there are more than one server in the cabinet, the fans are powered on without reference to working status of the servers. For example, if only one server is operating in the cabinet, all of the fans are powered on through the power supply unit. This is a waste of energy.

### BRIEF DESCRIPTION OF THE DRAWINGS

Many aspects of the embodiments can be better understood with reference to the following drawings. The components in the drawing are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of an exemplary embodiment of a server.

FIG. 2 is a block diagram of the server of FIG. 1, wherein the server includes first and second subsystems and a backplane.

FIG. 3 is a circuit diagram of the first subsystem and the backplane of FIG. 1.

FIG. 4 is a circuit diagram of the second subsystem and the backplane of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

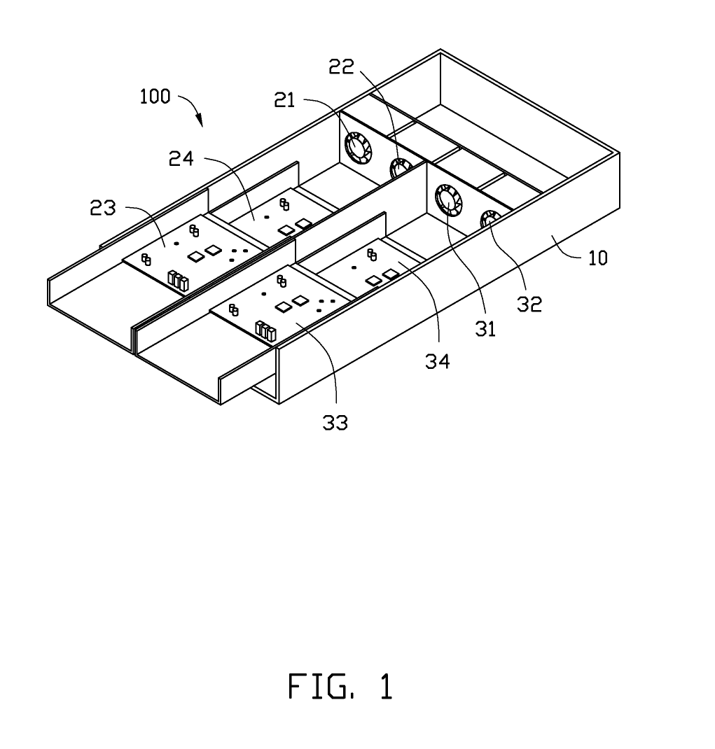

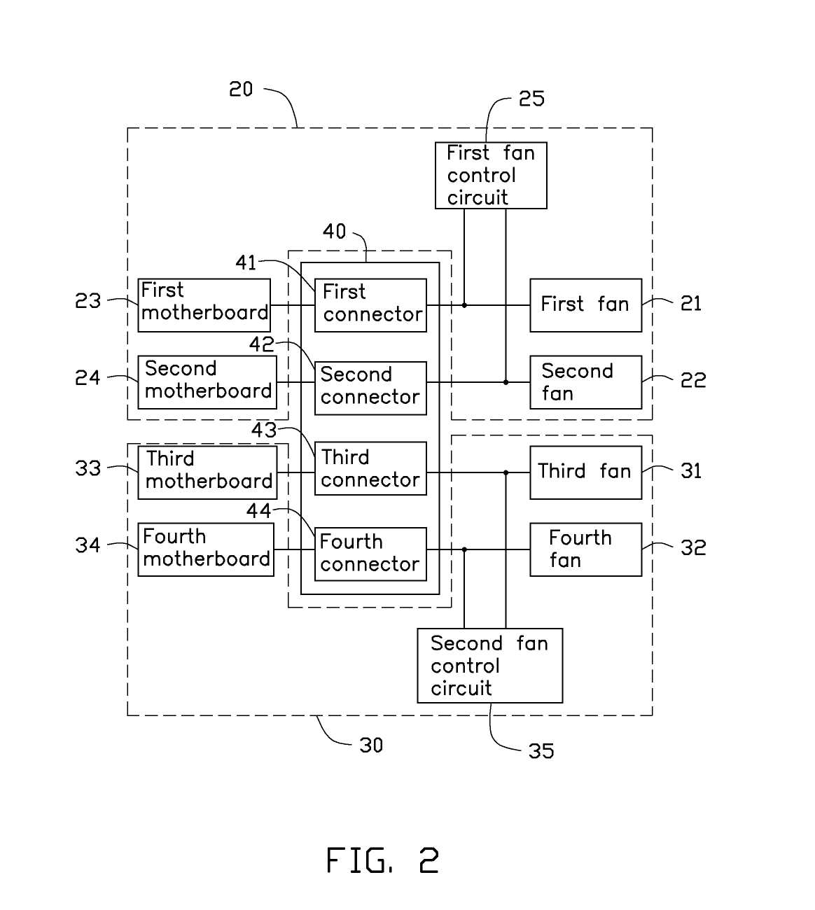

Referring to FIGS. 1-4, an exemplary embodiment of a server 100 is shown. The server 100 includes a chassis 10, a first subsystem 20, a second subsystem 30, and a backplane 40.

First and second groups of connectors are set on the backplane 40. In the embodiment, the first group of connectors includes a first connector 41 and a second connector 42. The second group of connectors includes a third connector 43 and a fourth connector 44.

The first subsystem 20 has same structure and function with the second subsystem 30. The first subsystem 20 is described as follows.

The first subsystem 20 includes a first group of fans, a first group of motherboards, and a first fan control circuit 25. In the embodiment, the first group of fans includes a first fan 21 and a second fan 22. The first group of motherboards includes a first motherboard 23 and a second motherboard 24.

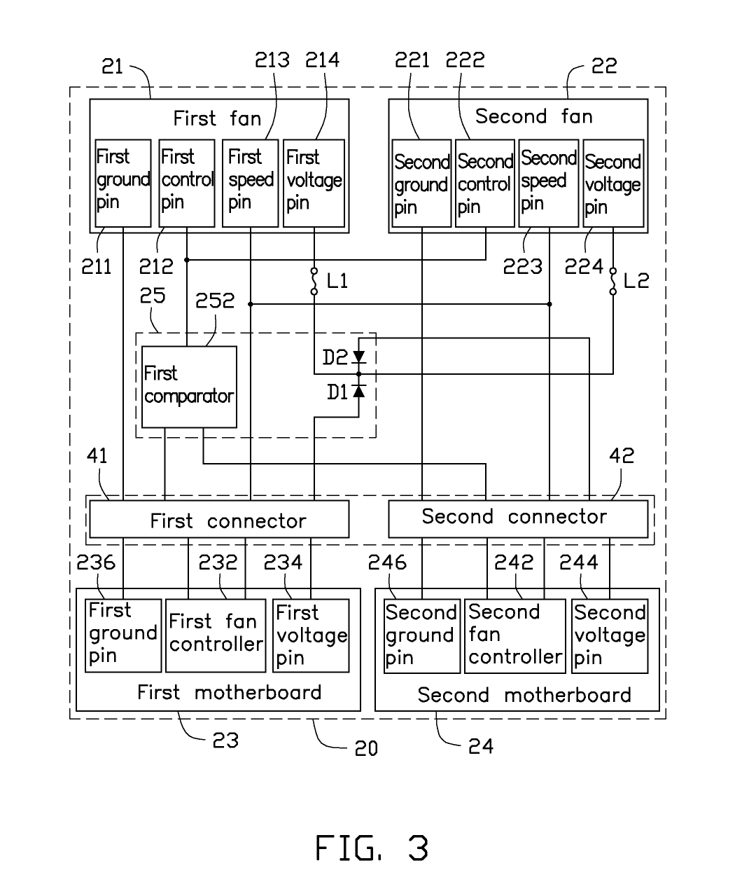

Referring to FIG. 3, the first motherboard 23 and the second motherboard 24 are mounted in the chassis 10 of the server 100, with the second motherboard 24 located below the first motherboard 23. A first fan controller 232, a first voltage pin 234, and a first ground pin 236 are set on the first motherboard 23. A second fan controller 242, a second voltage pin 244, and a second ground pin 246 are set on the second motherboard 24.

The first fan 21 and the second fan 22 are mounted in the chassis 10, respectively behind the first motherboard 23 and the second motherboard 24. The first fan 21 includes a first ground pin 211, a first control pin 212, a first speed pin 213, and a first voltage pin 214. The second fan 22 includes a second ground pin 221, a second control pin 222, a second speed pin 223, and a second voltage pin 224.

The first fan control circuit 25 includes a first comparator 252, a first diode D1, and a second diode D2.

The first ground pin 211 of the first fan 21 is connected to the first ground pin 236 of the first motherboard 23 through the first connector 41 of the backplane 40. The first speed pin 213 of the first fan 21 is connected to the first fan controller 232 of the first motherboard 23 through the first connector 41, for outputting a first speed signal to the first fan controller 232. The first speed pin 213 of the first fan 21 is connected to the second fan controller 242 on the second motherboard 24 through the second connector 42, for outputting the first speed signal to the second fan controller 242. The first voltage pin 214 of the first fan 21 is connected to a first terminal of a first fuse L1. A second terminal of the first fuse L1 is connected to cathodes of the first and second diodes D1 and D2. An anode of the first diode D1 is connected to the first voltage pin 234 on the first motherboard 23 through the first connector 41 on the backplane 40. The first control pin 212 of the first fan 21 is connected to an output pin of the first comparator 252.

The second ground pin 221 of the second fan 22 is connected to the second ground pin 246 of the second motherboard 24 through the second connector 42 on the backplane 40. The second speed pin 223 of the second fan 22 is connected to the second fan controller 242 on the second motherboard 24 through the second connector 42 on the backplane 40, for outputting a second speed signal to the second fan controller 242. The second speed pin 223 of the second fan 22 is further connected to the first fan controller 232 on the first motherboard 23 through the first connector 41 on the backplane 40, for outputting the second speed signal to the first fan controller 232. The second voltage pin 224 of the second fan 22 is connected to a first terminal of a second fuse L2. A second terminal of the second fuse L2 is connected to cathodes of the first and second diodes D1 and D2. An anode of the second diode D2 is connected to the second voltage pin 244 on the second motherboard 24 through the second connector 42 on the backplane 40. The second control pin 222 of the second fan 22 is connected to the output pin of the first comparator 252.

A first input pin of the first comparator 252 is connected to the first fan controller 232 on the first motherboard 23 through the first connector 41 on the backplane 40, for receiving a first pulse-width modulation (PWM) signal. A second input pin of the first comparator 252 is connected to the second fan controller 242 on the second motherboard 24 through the second connector 42 on the backplane 40, for receiving a second PWM signal. The first comparator 252 compares the first PWM signal with the second PWM signal, and outputs one of the PWM signals with a greater duty cycle to the first control pin 212 of the first fan 21 and the second control pin 222 of the second fan 22, for controlling the first fan 21 and the second fan 22 to operate at greater speeds.

When the first motherboard 23 and the second motherboard 24 are operating, the first voltage pin 234 of the first motherboard 23 outputs a voltage to the anode of the first diode D1, and the second voltage pin 244 of the second motherboard 24 outputs a voltage to the anode of the second diode D2. The first diode D1 and the second diode D2 are turned on. The first fan 21 and the second fan 22 are powered on.

When one of the first motherboard 23 or the second motherboard 24 is not operating, such as the first motherboard 23 is not operating but the second motherboard 234 is operating, the first voltage pin 234 of the first motherboard 23 does not output the voltage, and the second voltage pin 244 of the second motherboard 24 outputs the voltage. In this condition, the first diode D1 is turned off, and the second diode D2 is turned on. The second voltage pin 244 of the second motherboard 24 outputs the voltage to the first fan 12 and the second fan 22. The first fan 21 and the second fan 22 are powered on.

When both the first motherboard 23 and the second motherboard 24 are not operating, the first voltage pin 234 of the first motherboard 23 and the second voltage pin 244 of the second motherboard 24 do not output the voltage. In this condition, the first diode D1 and the second diode D2 are turned off. The first fan 21 and the second fan 22 are not powered on.

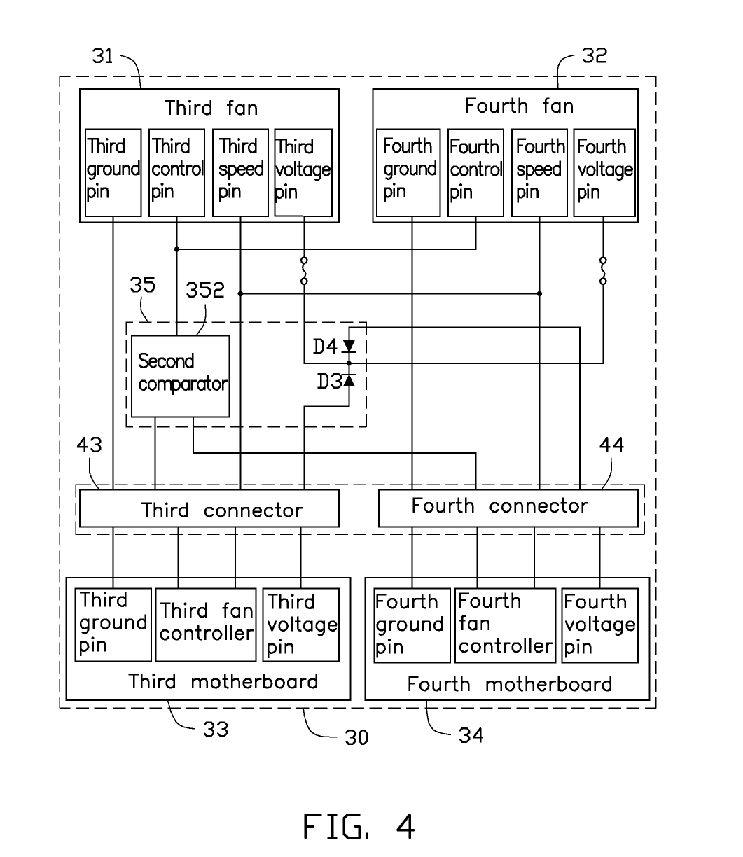

Referring to FIG. 4, the second subsystem 30 has the same structure as the first subsystem 20. When third and fourth motherboards 33 and 34 of the second subsystem 30 are operating, a third voltage pin 334 of the third motherboard 33 outputs the voltage to an anode of a third diode D3, and a fourth voltage pin 344 of the fourth motherboard 34 outputs the voltage to an anode of a fourth diode D4. The third and fourth diodes D3 and D4 are turned on. The third fan 31 and the fourth fan 32 are powered on.

When one of the third motherboard 33 and the fourth motherboard 34 are not operating, such as the third motherboard 33 is not operating but the fourth motherboard 34 is operating, the third voltage pin 334 of the third motherboard 33 does not output the voltage, and the fourth voltage pin 344 of the fourth motherboard 34 outputs the voltage. In this condition, the third diode D3 is turned off, and the fourth diode D4 is turned on. The fourth voltage pin 344 of the fourth motherboard 34 outputs the voltage to the third fan 31 and the fourth fan 32. The third fan 31 and the fourth fan 32 are powered on.

When both of the third motherboard 33 and the fourth motherboard 34 are not operating, the third voltage pin 334 of the third motherboard 33 and the fourth voltage pin 344 of the fourth motherboard 34 do not output the voltage. In this condition, the third diode D3 and the fourth diode D4 are turned off. The third fan 31 and the fourth fan 32 are not powered on.

As a result, when one of the first motherboard 23 or the second motherboard 24 is operating, the first fan 21 and the second fan 22 are operating. When both the third and fourth motherboards 33 and 34 are not operating, the third and fourth fans 31 and 32 are powered off. In other words, when one of the first and second groups of motherboards is not operating, the corresponding group of fans are powered off.

In the embodiment, when an inrush current or a spike voltage of the fans occurs, the first and second fuses L1 and L2 cut off to protect the server 100.

The foregoing description of the exemplary embodiments of the disclosure has been presented only for the purposes of illustration and description and is not intended to be exhaustive or to limit the disclosure to the precise forms disclosed. Many modifications and variations are possible in the light of everything above. The embodiments were chosen and described in order to explain the principles of the disclosure and their practical application so as to enable others of ordinary skill in the art to utilize the disclosure and various embodiments with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A server, comprising:
a backplane comprising a first group of connectors and a second group of connectors;
a first group of motherboards;
a second group of motherboards;
a first group of fans, wherein voltage pins of the first group of fans are connected to the first group of motherboards through the first group of connectors; and
a second group of fans, wherein voltage pins of the second group of fans are connected to the second group of motherboards through the second group of connectors;
wherein when the first group of motherboards are not operating, the first group of motherboards do not output power, the first group of fans are not powered on; when the second group of motherboards are not operating, the second group of motherboards do not output power, the second group of fans are not powered on; when at least one motherboard in the first group of motherboards is operating, the working motherboard outputs power to the first group of fans, the first group of fans are powered on; when at least one motherboard in the second group of motherboards is operating, the working motherboard outputs power to the second group of fans, the second group of fans are powered on.

2. The server of claim 1, wherein the first group of fans comprises a first fan and a second fan, the first group of motherboards comprises a first motherboard and a second motherboard, the first group of connectors comprises a first connector and a second connector, the second group of fans comprises a third fan and a fourth fan, the second group of motherboards comprises a third motherboard and a fourth motherboard, the second group of connectors comprises a third connector and a fourth connector; wherein the server further comprises first to fourth diodes, the voltage pin of the first fan is connected to cathodes of the first and second diodes, the voltage pin of the second fan is connected to the cathodes of the first and second diodes, an anode of the first diode is connected to the voltage pin of the first motherboard through the first connector, an anode of the second diode is connected to the voltage pin of the second motherboard through the second connector, the voltage pin of the third fan is connected to cathodes of the third and fourth diodes, the voltage pin of the fourth fan is connected to the cathodes of the third and fourth diodes, an anode of the third diode is connected to the voltage pin of the third motherboard through the third connector, an anode of the fourth diode is connected to the voltage pin of the fourth motherboard through the fourth connector.

3. The server of claim 2, further comprising a first comparator and a second comparator, wherein the first motherboard comprises a first fan controller, the second motherboard comprises a second fan controller, the third motherboard comprises a third fan controller, the fourth motherboard comprises a fourth fan controller; a first input pin of the first comparator is connected to the first fan controller through the first connector for receiving a first pulse-width modulation (PWM) signal, a second input pin of the first comparator is connected to the second fan controller through the second connector for receiving a second PWM signal, an output pin of the first comparator is connected to control pins of the first and second fans, the first comparator compares the first PWM signal with the second PWM signal and outputs one of the first and second PWM signals with a greater duty cycle to the control pins of the first and second fans; a first input pin of the second comparator is connected to the third fan controller through the third connector for receiving a third PWM signal, a second input pin of the second comparator is connected to the fourth fan controller through the fourth connector for receiving a fourth PWM signal, an output pin of the second comparator is connected to control pins of the third and fourth fans, the second comparator compares the third PWM signal with the fourth PWM signal and outputs one of the third and fourth PWM signals with a greater duty cycle to the control pins the third and fourth fans.

4. The server of claim 2, wherein speed pins of the first and second fans are connected to the first fan controller through the first connector for transmitting speed signals of the first and second fans to the first fan controller, the speed pins of the first and second fans are further connected to the second fan controller through the second connector for transmitting the speed signals of the first and second fans to the second fan controller; speed pins of the third and fourth fans are connected to the third fan controller through the third connector for transmitting speed signals of the third and fourth fans to the third fan controller, the speed pins of the third and fourth fans are further connected to the fourth fan controller through the fourth connector for transmitting the speed signals of the third and fourth fans to the fourth fan controller.
